(19) United States
(12) Patent Application Publication
(10) Pub. No.: US 2022/0157982 A1
(43) Pub. Date: May 19, 2022

(54) HIGH VOLTAGE DEVICE OF SWITCHING POWER SUPPLY CIRCUIT AND MANUFACTURING METHOD THEREOF

(71) Applicant: RICHTEK TECHNOLOGY CORPORATION, Zhubei City (TW)

(72) Inventors: Kuo-Chin Chiu, Hsinchu (TW); Ta-Yung Yang, Taoyuan (TW); Chien-Wei Chiu, Yunlin (TW); Wu-Te Weng, Hsinchu (TW); Chien-Yu Chen, Kaohsiung (TW); Chih-Wen Hsiung, Hsinchu (TW); Chun-Lung Chang, Yilan (TW); Kun-Huang Yu, Hsinchu (TW); Ting-Wei Liao, Taichung (TW)

(21) Appl. No.: 17/506,422

(22) Filed: Oct. 20, 2021

(30) Foreign Application Priority Data
Nov. 19, 2020 (TW) 109140632

(51) Int. Cl. H01L 29/78; H01L 29/872; H01L 29/66

(52) U.S. Cl. CPC H01L 29/782; H01L 29/66689; H01L 29/872; H01L 29/7824

(57) ABSTRACT

A high voltage device for use as an up-side switch of a power stage circuit includes: at least one lateral diffused metal oxide semiconductor (LDMOS) device, a second conductivity type isolation region and at least one Schottky barrier diode (SBD). The LDMOS device includes: a well formed in a semiconductor layer, a body region, a gate, a source and a drain. The second conductivity type isolation region is formed in the semiconductor layer and is electrically connected to the body region. The SBD includes: a Schottky metal layer formed on the semiconductor layer and a Schottky semiconductor layer formed in the semiconductor layer. The Schottky semiconductor layer and the Schottky metal layer form a Schottky contact. In the semiconductor layer, the Schottky semiconductor layer is adjacent to and in contact with the second conductivity type isolation region.

### CROSS REFERENCE

The present invention claims priority to TW 109140632 filed on Nov. 19, 2020.

### BACKGROUND OF THE INVENTION

### Field of Invention

The present invention relates to a high voltage device of a switching regulator and a manufacturing method thereof; particularly, the present invention relates to such a high voltage device which can eliminate leakage current and a manufacturing method thereof.

### Description of Related Art

Please refer to FIG. 1, which shows a schematic circuit diagram of a conventional boost power stage circuit, which is for use as a power stage circuit of a switching regulator. As shown in FIG. 1, during a dead time, when a current Ibd flows from the phase node LX to the output voltage Vout, such current Ibd will flow through a parasitic diode of the transistor device to generate a leakage current Ib, which will turn ON a parasitic PNP transistor to be turned ON, to further generate a leakage current Ic. The leakage current Ic will flow from the phase node LX to the ground level GND. From device perspective, the leakage current Ic will flow from a P-type isolation ring and an N-type isolation ring to a P-type substrate, causing power loss. Such undesirable leakage current issue will occur at the lateral sides and the bottom side of the device.

In view of the above, to overcome the drawbacks in the prior art, the present invention proposes a high voltage device of a switching regulator and a manufacturing method thereof, which are capable of eliminating leakage current.

### SUMMARY OF THE INVENTION

From one perspective, the present invention provides a high voltage device for use as an up-side switch in a power stage circuit of a switching regulator, the high voltage device comprising: at least one lateral diffused metal oxide semiconductor (LDMOS) device, wherein the at least one LDMOS device includes: a well, which has a first conductivity type, and is formed in a semiconductor layer; a body region, which has a second conductivity type, and is formed in the well; a gate, which is formed on the well and is connected to the well; and a source and a drain, which have the first conductivity type, and are located at different sides out of the gate respectively, wherein the source is located in the body region, and the drain is located in the well; a second conductivity type isolation region, which is formed in the semiconductor layer, wherein the second conductivity type isolation region encompasses a lateral side of and a bottom side of the at least one LDMOS device, and wherein the second conductivity type isolation region is electrically connected to the body region; and at least one Schottky barrier diode (SBD), wherein the at least one SBD includes: a Schottky metal layer, which is formed on the semiconductor layer, and is electrically connected to an offset voltage; and a Schottky semiconductor layer, which has the first conductivity type, and is formed in the semiconductor layer, wherein the Schottky semiconductor layer and the Schottky metal layer form a Schottky contact, and wherein in the semiconductor layer, the Schottky semiconductor layer is adjacent to and in contact with the second conductivity type isolation region; wherein part of the body region, which is between a boundary thereof and the source, and is vertically below the gate, forms an inversion region which serves as an inversion current channel in an ON operation of the LDMOS device; wherein part of the well between the body region and the drain is a drift region, which serves as a drift current channel in the ON operation of the LDMOS device.

In one embodiment, the at least one SBD is located in a first conductivity type isolation region of the high voltage device, and wherein the first conductivity type isolation region is located outside of the second conductivity type isolation region, and the first conductivity type isolation region encompasses a lateral side of and a bottom side of the second conductivity type isolation region.

In one embodiment, the high voltage device further comprises: a substrate region, which has the second conductivity type and which encompasses a lateral side of and a bottom side of the first conductivity type isolation region.

In one embodiment, the at least one LDMOS device further includes: adrift oxide region, which is formed on the drift region, wherein the drift oxide region includes: a LOCal Oxidation of Silicon (LOCOS) structure, a Shallow Trench Isolation (STI) structure or a Chemical Vapor Deposition (CVD) structure.

In one embodiment, the gate includes: a dielectric layer, which is formed on the body region and the well and is connected to the body region and the well; a conductive layer, which serves as an electrical contact of the gate, wherein the conductive layer is formed on the dielectric layer and is connected to the dielectric layer; and a spacer layer, which is formed out of two sides of the conductive layer and serves as an electrically insulative layer at two sides of the gate.

In one embodiment, the Schottky metal layer is electrically connected to a current outflow end of the power stage circuit.

From another perspective, the present invention provides a manufacturing method of a high voltage device, wherein the high voltage device is for use as an up-side switch in a power stage circuit of a switching regulator; the manufacturing method comprising: forming at least one lateral diffused metal oxide semiconductor (LDMOS) device, by manufacturing steps including: forming a well in a semiconductor layer, wherein the well has a first conductivity type; forming a body region in the well, wherein the body region has a second conductivity type; forming a gate on the well and in contact with the well; and forming a source and a drain having the first conductivity, wherein the source and the drain are located at different sides out of the gate respectively, wherein the source is located in the body region, and the drain is located in the well; forming a second conductivity type isolation region in the semiconductor layer, wherein the second conductivity type isolation region encompasses a lateral side of and a bottom side of the at least one LDMOS device, and wherein the second conductivity type isolation region is electrically connected to the body region; and forming at least one Schottky barrier diode (SBD), by manufacturing steps including: forming a Schottky metal layer on the semiconductor layer, wherein the Schottky metal layer is electrically connected to an offset voltage; and forming a Schottky semiconductor layer in the semiconductor layer, wherein the Schottky semiconductor layer and the Schottky metal layer form a Schottky contact, and wherein in the semiconductor layer, the Schottky semiconductor layer is adjacent to and in contact with the second conductivity type isolation region, wherein the Schottky semiconductor layer has the first conductivity type; wherein part of the body region, which is between a boundary thereof and the source, and is vertically below the gate, forms an inversion region which serves as an inversion current channel in an ON operation of the LDMOS device; wherein part of the well between the body region and the drain is a drift region, which serves as a drift current channel in the ON operation of the LDMOS device.

In one embodiment, the manufacturing method further comprises: forming a first conductivity type isolation region in the semiconductor layer of the high voltage device, so that the at least one SBD is located in the first conductivity type isolation region, wherein the first conductivity type isolation region is located outside of the second conductivity type isolation region, and the first conductivity type isolation region encompasses a lateral side of and a bottom side of the second conductivity type isolation region.

In one embodiment, the manufacturing method further comprises: forming a substrate region at a lateral side of and a bottom side of the first conductivity type isolation region, wherein the substrate region encompasses the lateral side of and the bottom side of the first conductivity type isolation region, wherein the substrate region has the second conductivity type.

In one embodiment, the manufacturing method further comprises: forming a drift oxide region on the drift region, wherein the drift oxide region includes: a LOCal Oxidation of Silicon (LOCOS) structure, a Shallow Trench Isolation (STI) structure or a Chemical Vapor Deposition (CVD) structure.

In one embodiment, the step for forming the gate includes: forming a dielectric layer on the body region and the well, wherein the dielectric layer is connected to the body region and the well; forming a conductive layer on the dielectric layer, wherein the conductive layer is connected to the dielectric layer and the conductive layer serves as an electrical contact of the gate; and forming a spacer layer out of two sides of the conductive layer, wherein the spacer layer serves as an electrically insulative layer at two sides of the gate.

In one embodiment, the Schottky metal layer is electrically connected to a current outflow end of the power stage circuit.

The present invention is advantageous in that: the present invention can eliminate leakage current at a lateral side of the first conductivity type isolation region along a horizontal direction and at a bottom side of the first conductivity type isolation region along a vertical direction.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic circuit diagram of a conventional boost power stage circuit.

FIG. 2 shows a cross-section view of a high voltage device configured to be used as an up-side switch in a power stage circuit of a switching regulator according to an embodiment of the present invention.

FIG. 3 shows a cross-section view of a high voltage device configured to be used as an up-side switch in a power stage circuit of a switching regulator according to another embodiment of the present invention.

FIGS. 4A-4M show a manufacturing method of a high voltage device according to an embodiment of the present invention.

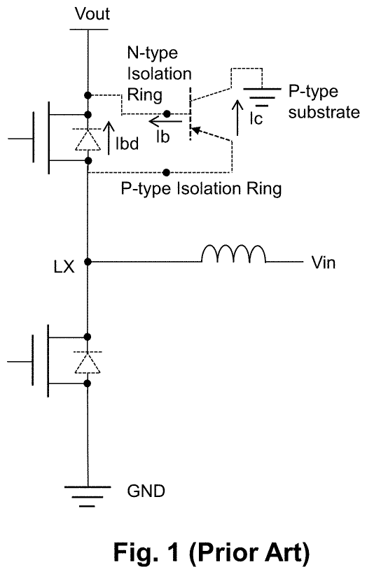

### DESCRIPTION OF THE PREFERRED EMBODIMENTS

The drawings as referred to throughout the description of the present invention are for illustration only, to show the interrelations among the process steps and the layers, but the shapes, thicknesses, and widths are not drawn in actual scale.

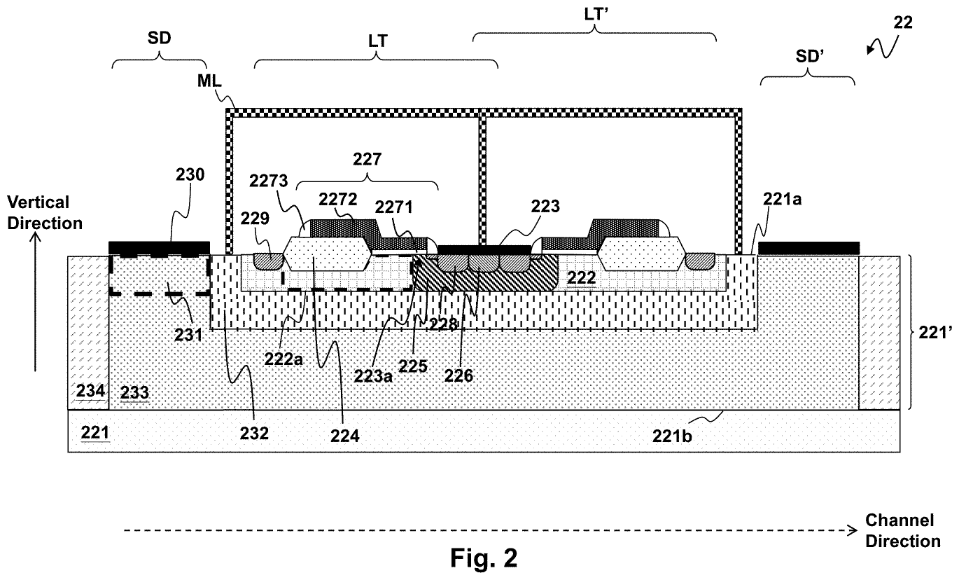

Please refer to FIG. 2, which shows a cross-section view of a high voltage device configured to be used as an up-side switch in a power stage circuit of a switching regulator according to an embodiment of the present invention. As shown in FIG. 2, the high voltage device 22 comprises: lateral diffused metal oxide semiconductor (LDMOS) devices LT and LT′, a second conductivity type isolation region 232 and Schottky barrier diodes (SBD) SD and SD′. This embodiment comprises two LDMOS devices, such as LDMOS device LT and LDMOS device LT′. However, it should be understood that the number of the LDMOS devices being two is only an illustrative example, but not for limiting the broadest scope of the present invention. In other embodiments, it is also practicable and within the scope of the present invention that the number for the LDMOS device can be one or more than two. The LDMOS device LT includes a well 222, a drift oxide region 224, a body region 225, a body contact 226, a gate 227, a source 228, and a drain 229.

A semiconductor layer 221′ is formed on the substrate 221. The semiconductor layer 221′ has a top surface 221a and a bottom surface 221b opposite to the top surface 221a in a vertical direction (as indicated by the direction of the solid arrow in FIG. 2). The substrate 221 is, for example but not limited to, a P-type or N-type semiconductor substrate. The semiconductor layer 221′, for example, is formed on the substrate 221 by an epitaxial process step, or is a part of the substrate 221. The semiconductor layer 221′ can be formed by various methods known to a person having ordinary skill in the art, so the details thereof are not redundantly explained here.

Still referring to FIG. 2, the drift oxide region 224 is formed on and in contact with the top surface 221a and is located on and in contact with part of a drift region 222a (as indicated by the dashed line frame shown in FIG. 2). The drift oxide region 224 is for example but not limited to a local oxidation of silicon (LOCOS) structure as shown in the figure, or it may be a shallow trench isolation (STI) structure or a chemical vapor deposition (CVD) structure in other embodiments.

The well 222 has the first conductivity type, and is formed in the semiconductor layer 221′. The well 222 is located beneath the top surface 221a and is in contact with the top surface 221a in the vertical direction. The well 222 is formed by for example but not limited to at least one ion implantation process step. The body region 225 has a second conductivity type, and is formed in the well 222. The body region 225 is located beneath and in contact with the top surface 221a in the vertical direction. The body contact 226 has the second conductivity type, and serves as an electrical contact of the body region 225. The body contact 226 is formed in the body region 225, beneath the top surface 221a and in contact with the top surface 221a in the vertical direction. The gate 227 is formed on the top surface 221a of the semiconductor layer 221′, wherein part of the body region 225 near the top surface 221a between the source 228 and the well 222 defines an inversion region 223a, as an inversion current channel in the ON operation of the LDMOS device LT, wherein the inversion region 223a is located vertically below the gate 227 and in contact with the gate 227 to provide the inversion current channel of the LDMOS device LT during the ON operation.

Still referring to FIG. 2, the source 228 and the drain 229 have the first conductivity type. The source 228 and the drain 229 are formed beneath the top surface 221a and in contact with the top surface 221a in the vertical direction. The source 228 and the drain 229 are located at two different sides out of the gate 227 respectively, wherein the source 228 is located in the body region 225, and the drain 229 is located in the well 222 which is away from the body region 225. In the channel direction, part of the well 222 which is near the top surface 221a, and between the body region 225 and the drain 229, defines the drift region 222a. The drift region 222a serves as a drift current channel in the ON operation of the LDMOS device LT.

Note that the term “inversion current channel” 223a means thus. Taking this embodiment as an example, when the LDMOS device LT operates in the ON operation due to the voltage applied to the gate 227, an inversion layer is formed beneath the gate 227, between the source 228 and the drift region 222a, so that a conduction current flows through the region of the inversion layer, which is the inversion current channel known to a person having ordinary skill in the art.

Note that the first conductivity type maybe P-type or N-type; when the first conductivity type is P-type, the second conductivity type is N-type, and when the first conductivity type is N-type, the second conductivity type is P-type.

Note that the term “drift current channel” means thus. Taking this embodiment as an example, the drift current channel refers to a region where the conduction current passes through in a drifting manner when the LDMOS device LT operates in the ON operation, which is known to a person having ordinary skill in the art.

Note that the top surface 221a as referred to does not mean a completely flat plane but refers to the surface of the semiconductor layer 221′, which may have its topology during processing. In the present embodiment, for example, a part of the top surface 221a where the drift oxide region 224 is in contact with has a recessed portion.

Note that the gate 227 as defined in the context of this invention includes a dielectric layer 2271 in contact with the top surface 221a, a conductive layer 2272 which is conductive, and a spacer layer 2273 which is electrically insulative. The dielectric layer 2271 is formed on the body region 225 and the well 222, and is in contact with the body region 225 and the well 222. The conductive layer 2272 serves as an electrical contact of the gate 227, and is formed on the dielectric layer 2271 and in contact with the dielectric layer 2271. The spacer layer 2273 is formed out of two sides of the conductive layer 2272, as an electrically insulative layer of the gate 227.

In addition, the term “high voltage” device means that, when the device operates in normal operation, the voltage applied to the drain is higher than a specific voltage, such as 5V; for devices of different high voltages, a lateral distance (distance of the drift region 222a) between the body region 225 and the drain 229 can be determined according to the operation voltage that the device is designed to withstand during normal operation, which is known to a person having ordinary skill in the art.

Still referring to FIG. 2, the second conductivity type isolation region 232 is formed in the semiconductor layer 221′. As shown in FIG. 2, in this embodiment, the second conductivity type isolation region 232 encompasses a lateral side of and a bottom side of the LDMOS devices LT and LT′. The second conductivity type isolation region 232 is electrically connected to the body region 225. The second conductivity type isolation region 232 and the body contact 226 are electrically connected to each other via a metal wire ML. The SBD SD includes: a Schottky metal layer 230 and a Schottky semiconductor layer 231. As shown in FIG. 2, in this embodiment, the Schottky metal layer 230 is formed on the semiconductor layer 221′ . The Schottky metal layer 230 is formed on and in contact with the top surface 221a in the vertical direction. The Schottky semiconductor layer 231 has the first conductivity type and is formed in the semiconductor layer 221′ . The Schottky semiconductor layer 231 and the Schottky metal layer 230 form a Schottky contact. In the semiconductor layer 221′, the Schottky semiconductor layer 231 is adjacent to and in contact with the second conductivity type isolation region 232. The Schottky semiconductor layer 231 is located beneath the top surface 221a and is in contact with the top surface 221a in the vertical direction. To be more specific, in the semiconductor layer 221′, the Schottky semiconductor layer 231 is adjacent to and in contact with a lateral side of the second conductivity type isolation region 232. The SBD SD is located in a first conductivity type isolation region 233 of the high voltage device 22. As shown in FIG. 2, in this embodiment, the first conductivity type isolation region 233 is located outside of the second conductivity type isolation region 232 and the first conductivity type isolation region 233 encompasses a lateral side of and a bottom side of the second conductivity type isolation region 232. The high voltage device 22 further comprises a substrate region. The substrate region has the second conductivity type and encompasses a lateral side of and a bottom side of the first conductivity type isolation region 233. In one embodiment, as shown in FIG. 2, the above-mentioned substrate region includes the substrate 221 and an external second conductivity type isolation region 234. The external second conductivity type isolation region 234 is adjacent to and in contact with the first conductivity type isolation region 233 and encompasses a lateral side of the first conductivity type isolation region 233. The substrate 221 encompasses a bottom side of the first conductivity type isolation region 233. In one embodiment, the Schottky metal layer 230 is electrically connected to an offset voltage. In one embodiment, the Schottky metal layer 230 is electrically connected to a current outflow end of a power stage circuit. In one preferred embodiment, the Schottky metal layer 230 is electrically connected to an output end of the power stage circuit.

Note that, in this embodiment, in the LDMOS devices (including the LDMOS devices LT and LT′), all the wells 222 are electrically connected to each other, and likely, all the body regions 225, all the body contacts 226, all the gates 227, all the sources 228, and all the drain 229 of the LDMOS devices are respectively electrically connected to each other. In the SBDs (including the SBDs SD and SD′), all the Schottky metal layers 230 are electrically connected to each other, and all the Schottky semiconductor layers 231 are electrically connected to each other. In a preferred embodiment, in the LDMOS device LT, the source 228 and the body contact 226 are electrically connected by a metal silicide layer 223 as shown in the figure.

The present invention is advantageous over the prior art; to explain, taking the embodiment shown in FIG. 2 as an example, in the present invention, the high voltage device 22 comprises Schottky barrier diodes (SBD) SD and SD′, which are formed in the first conductivity type isolation region 233 to serve as an up-side device of a power stage circuit. Because the Schottky barrier diodes (SBD) SD and SD′ of the high voltage device 22 has a diode characteristic, it can prevent the parasitic PNP transistor from being turned ON by a leakage current generated when the high voltage device operates in a dead time. As a result, the leakage current at the lateral side of the first conductivity type isolation region 233 along a horizontal direction (i.e., a channel direction) and at the bottom side of the first conductivity type isolation region 233 along a vertical direction can be eliminated.

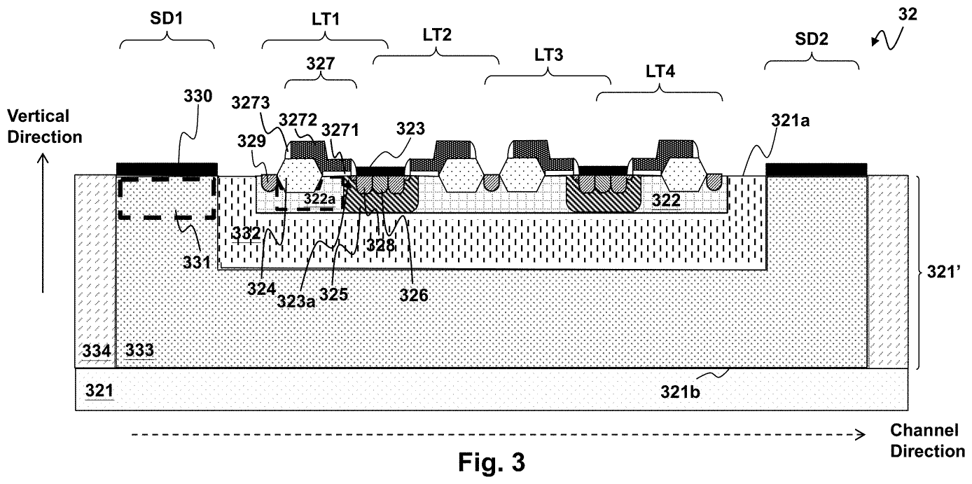

Please refer to FIG. 3, which shows a cross-section view of a high voltage device configured to be used as an up-side switch in a power stage circuit of a switching regulator according to another embodiment of the present invention. As shown in FIG. 3, in this embodiment, the high voltage device 32 can comprise more than two LDMOS devices, such as four LDMOS devices. As shown in FIG. 3, these four LDMOS devices LT1, LT2, LT3 and LT4 are formed between two SBDs SD1 and SD2. As shown in FIG. 3, the LDMOS device LT2 and the LDMOS device LT3 can share one drain 329.

As shown in FIG. 3, the high voltage device 32 comprises: lateral diffused metal oxide semiconductor (LDMOS) devices (LDMOS devices) LT1, LT2, LT3 and LT4, a second conductivity type isolation region 332 and Schottky barrier diodes (SBD) SD1 and SD2. This embodiment comprises four LDMOS devices, such as LDMOS device LT1 LDMOS device LT2, LDMOS device LT3 and LDMOS device LT4. Certainly, it should be understood that the number for the LDMOS device being four is only an illustrative example, but not for limiting the broadest scope of the present invention. In other embodiments, it is also practicable and within the scope of the present invention that the number for the LDMOS device can be any plural number other than four. The LDMOS device LT1 includes a well 322, a drift oxide region 324, a body region 325, a body contact 326, a gate 327, a source 328, and a drain 329.

In the high voltage device 32, the semiconductor layer 321′ is formed on the substrate 321. The semiconductor layer 321′ has a top surface 321a and a bottom surface 321b opposite to the top surface 321a in a vertical direction (as indicated by the direction of the solid arrow in FIG. 3). The substrate 321 is, for example but not limited to, a P-type or N-type semiconductor substrate. The semiconductor layer 321′, for example, is formed on the substrate 321 by an epitaxial process step, or is a part of the substrate 321. The semiconductor layer 321′ can be formed by various methods known to a person having ordinary skill in the art, so the details thereof are not redundantly explained here.

Still referring to FIG. 3, the drift oxide region 324 is formed on and in contact with the top surface 321a and is located on and in contact with part of a drift region 322a (as indicated by the dashed line frame shown in FIG. 3). The drift oxide region 324 is for example but not limited to a local oxidation of silicon (LOCOS) structure as shown in the figure, or it may be a shallow trench isolation (STI) structure or a chemical vapor deposition (CVD) structure in other embodiments.

The well 322 has the first conductivity type, and is formed in the semiconductor layer 321′. The well 322 is located beneath the top surface 321a and is in contact with the top surface 321a in the vertical direction. The well 322 is formed by for example but not limited to at least one ion implantation process step. The body region 325 has the second conductivity type, and is formed in the well 322. The body region 325 is located beneath and in contact with the top surface 321a in the vertical direction. The body contact 326 has the second conductivity type, and serves as an electrical contact of the body region 325. The body contact 326 is formed in the body region 325, beneath the top surface 321a and in contact with the top surface 321a in the vertical direction. The gate 327 is formed on the top surface 321a of the semiconductor layer 321′, wherein part of the body region 325 near the top surface 321a between the source 328 and the well 322 defines an inversion region 323a, as an inversion current channel in the ON operation of the LDMOS device LT1, wherein the inversion region 323 is located vertically below the gate 327 and in contact with the gate 327 to provide the inversion current channel of the LDMOS device LT1 during the ON operation.

Still referring to FIG. 3, the source 328 and the drain 329 have the first conductivity type. The source 328 and the drain 329 are formed beneath the top surface 321a and in contact with the top surface 321a in the vertical direction. The source 328 and the drain 329 are located at two different sides out of the gate 327 respectively, wherein the source 328 is located in the body region 325, and the drain 329 is located in the well 322 which is away from the body region 325. In the channel direction, part of the well 322 which is near the top surface 321a, and between the body region 325 and the drain 329, defines the drift region 322a. The drift region 322a serves as a drift current channel in the ON operation of the LDMOS device LT1.

Note that the term “inversion current channel” 323a means thus. Taking this embodiment as an example, when the LDMOS device LT1 operates in the ON operation due to the voltage applied to the gate 327, an inversion layer is formed beneath the gate 327, between the source 328 and the drift region 322a, so that a conduction current flows through the region of the inversion layer, which is the inversion current channel known to a person having ordinary skill in the art.

Note that the first conductivity type maybe P-type or N-type; when the first conductivity type is P-type, the second conductivity type is N-type, and when the first conductivity type is N-type, the second conductivity type is P-type.

Note that the term “drift current channel” means thus. Taking this embodiment as an example, the drift current channel refers to a region where the conduction current passes through in a drifting manner when the LDMOS device LT1 operates in the ON operation, which is known to a person having ordinary skill in the art.

Note that the top surface 321a as referred to does not mean a completely flat plane but refers to the surface of the semiconductor layer 321′, which may have its topology during processing. In the present embodiment, for example, a part of the top surface 321a where the drift oxide region 324 is in contact with has a recessed portion.

Note that the gate 327 as defined in the context of this invention includes a dielectric layer 3271 in contact with the top surface 321a, a conductive layer 3272 which is conductive, and a spacer layer 3273 which is electrically insulative. The dielectric layer 3271 is formed on the body region 325 and the well 322, and is in contact with the body region 325 and the well 322. The conductive layer 3272 serves as an electrical contact of the gate 327, and is formed on the dielectric layer 3271 and in contact with the dielectric layer 3271. The spacer layer 3273 is formed out of two sides of the conductive layer 3272, as an electrically insulative layer of the gate 327.

In addition, the term “high voltage” device means that, when the device operates in normal operation, the voltage applied to the drain is higher than a specific voltage, such as 5V; for devices of different high voltages, a lateral distance (distance of the drift region 322a) between the body region 325 and the drain 329 can be determined according to the operation voltage that the device is designed to withstand during normal operation, which is known to a person having ordinary skill in the art.

Still referring to FIG. 3, the second conductivity type isolation region 332 is formed in the semiconductor layer 321′. As shown in FIG. 2, in this embodiment, the second conductivity type isolation region 232 encompasses a lateral side of and a bottom side of the LDMOS devices LT1, LT2, LT3 and LT4. The second conductivity type isolation region 332 is electrically connected to the body region 325. The second conductivity type isolation region 332 and the body contact 326 are electrically connected to each other via a metal wire (not shown in FIG. 3; instead, please refer to FIG. 2). The SBD SD1 includes a Schottky metal layer 330 and a Schottky semiconductor layer 331. As shown in FIG. 3, in this embodiment, the Schottky metal layer 330 is formed on the semiconductor layer 321′. The Schottky metal layer 330 is formed on and in contact with the top surface 321a in the vertical direction. The Schottky semiconductor layer 331 has the first conductivity type and is formed in the semiconductor layer 321′. The Schottky semiconductor layer 331 and the Schottky metal layer 330 form a Schottky contact. In the semiconductor layer 321′, the Schottky semiconductor layer 331 is adjacent to and in contact with the second conductivity type isolation region 332. The Schottky semiconductor layer 331 is located beneath the top surface 321a and is in contact with the top surface 321a in the vertical direction. To be more specific, in the semiconductor layer 321′, the Schottky semiconductor layer 331 is adjacent to and in contact with a lateral side of the second conductivity type isolation region 332. In this embodiment, the SBD SD1 is located in a first conductivity type isolation region 333 of the high voltage device 32. As shown in FIG. 3, in this embodiment, the first conductivity type isolation region 333 is located outside of the second conductivity type isolation region 332 and the first conductivity type isolation region 333 encompasses a lateral side of and a bottom side of the second conductivity type isolation region 332. The high voltage device 32 further comprises a substrate region. The substrate region has the second conductivity type and encompasses a lateral side of and a bottom side of the first conductivity type isolation region 333. In one embodiment, as shown in FIG. 3, the above-mentioned substrate region can include: the substrate 321 and an external second conductivity type isolation region 334. The external second conductivity type isolation region 334 is adjacent to and in contact with the first conductivity type isolation region 333 and encompasses a lateral side of the first conductivity type isolation region 333. The substrate 221 encompasses a bottom side of the first conductivity type isolation region 233. In one embodiment, the Schottky metal layer 330 is electrically connected to an offset voltage. In one embodiment, the Schottky metal layer 330 is electrically connected to a current outflow end of a power stage circuit. In one embodiment, the Schottky metal layer 330 is electrically connected to an output end of the power stage circuit.

Note that, in this embodiment, in the LDMOS devices (including the LDMOS devices LT1, LT2, LT3 and LT4), all the wells 322 are electrically connected to each other, and likely, all the body regions 325, all the body contacts 326, all the gates 327, all the sources 328, and all the drain 329 of the LDMOS devices are respectively electrically connected to each other. In the SBDs (including the SBDs SD1 and SD2), all the Schottky metal layers 330 are electrically connected to each other, and all the Schottky semiconductor layers 331 are electrically connected to each other. In a preferable embodiment, in the LDMOS device LT1, the source 328 and the body contact 326 are electrically connected by a metal silicide layer 323 as shown in the figure.

The present invention is advantageous over the prior art; to explain, taking the embodiment shown in FIG. 3 as an example, in the present invention, the high voltage device 32 comprises Schottky barrier diodes (SBD) SD1 and SD2, which are formed in the first conductivity type isolation region 333, whereby the leakage current at the lateral side of the first conductivity type isolation region 333 along a horizontal direction (i.e., a channel direction) and at the bottom side of the first conductivity type isolation region 333 along a vertical direction can be eliminated.

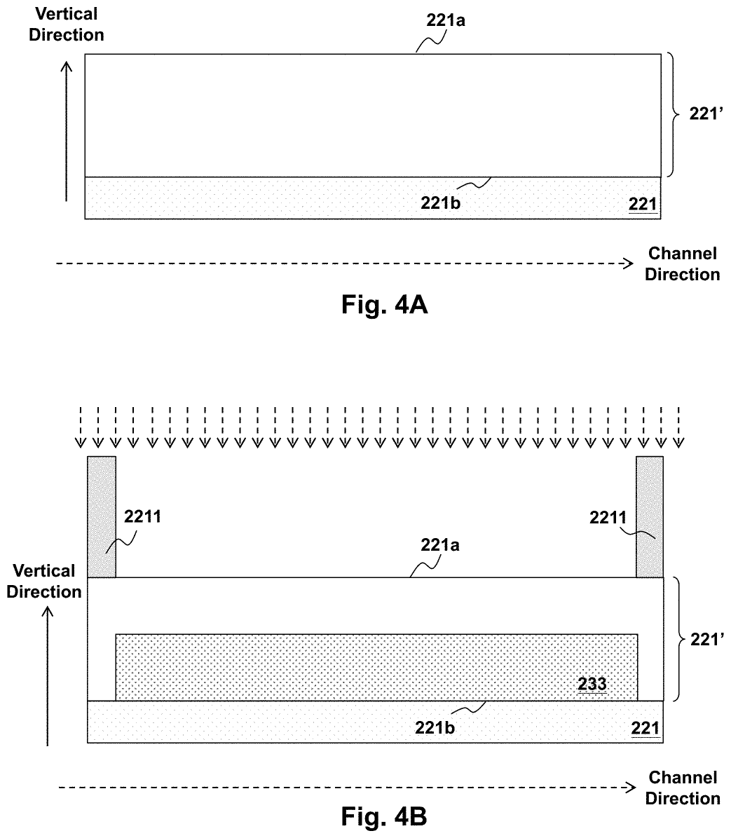

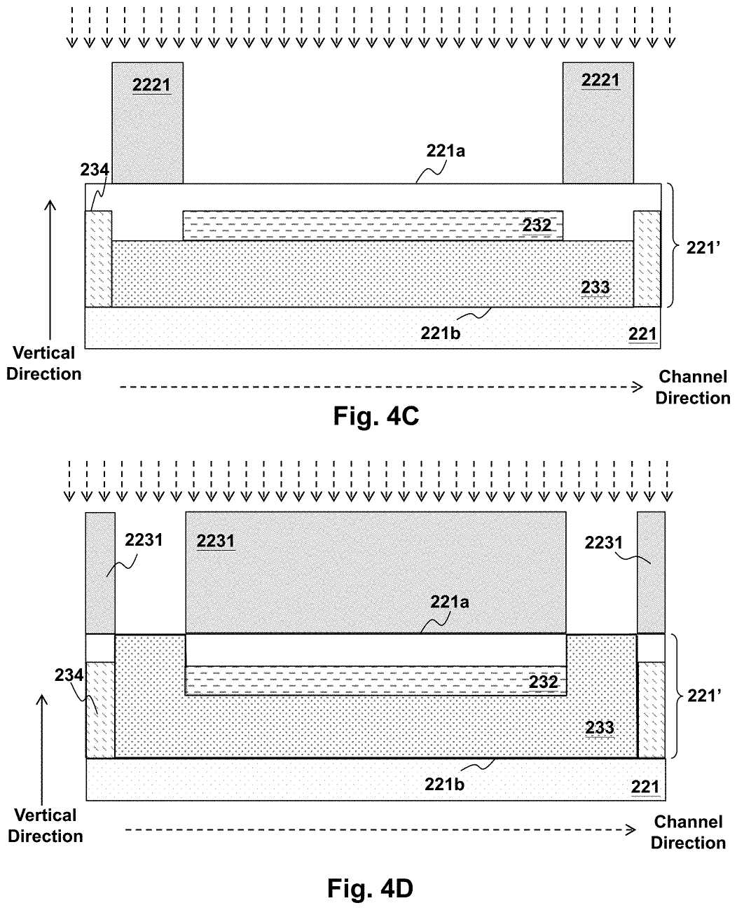

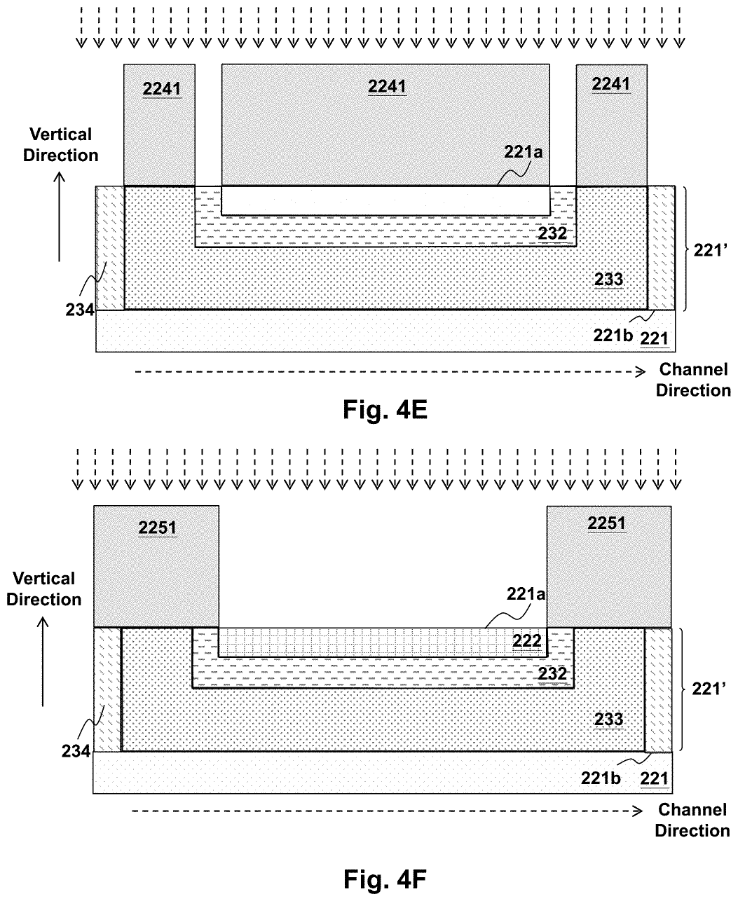

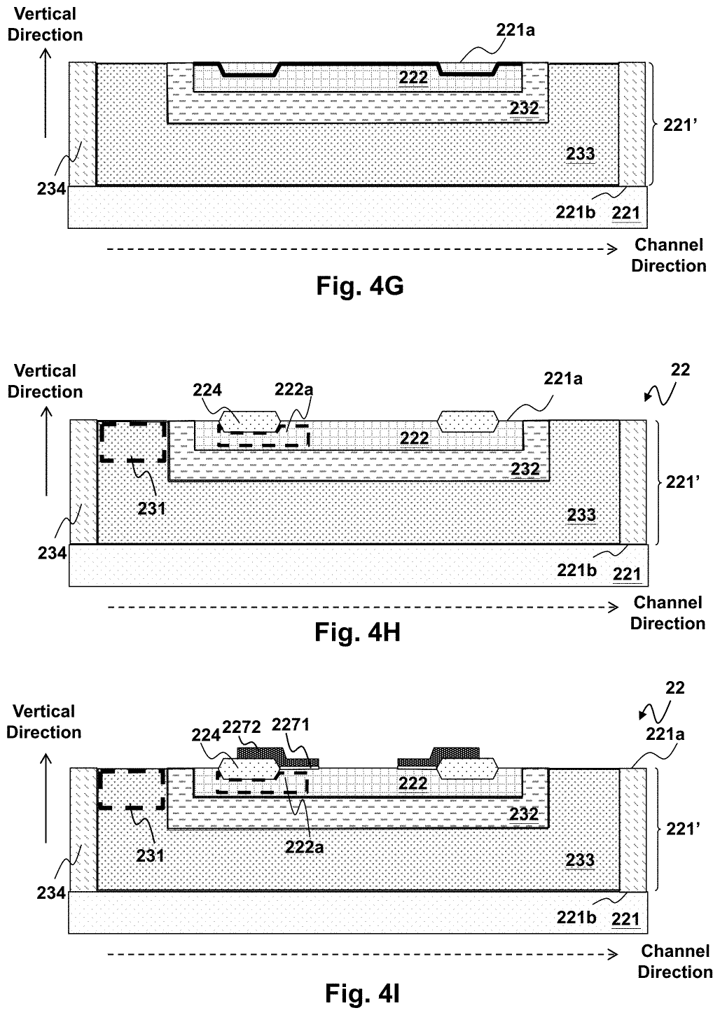

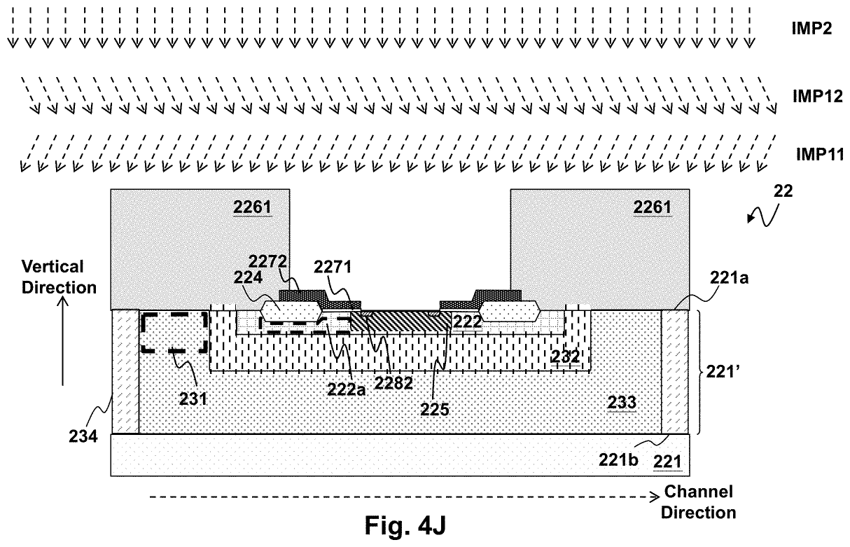

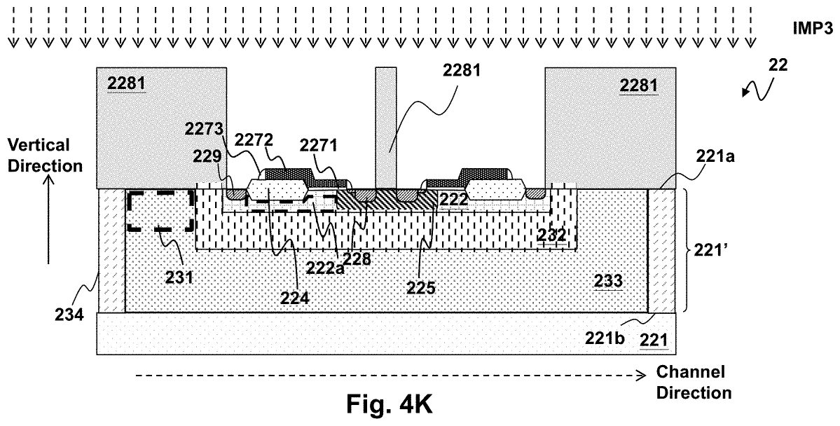

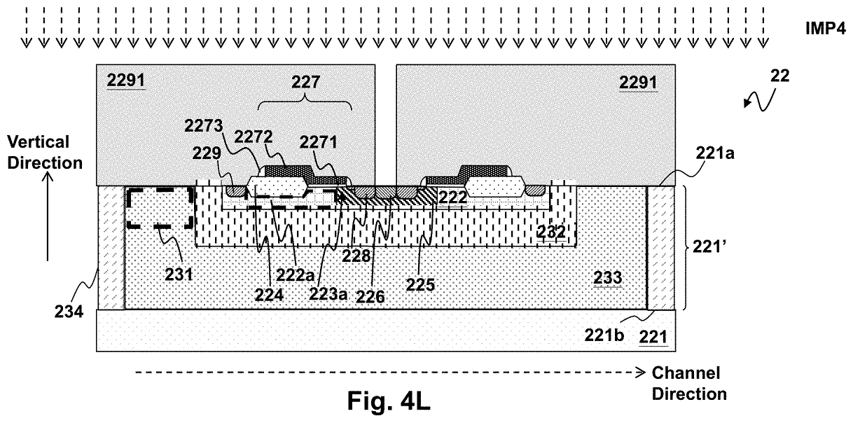

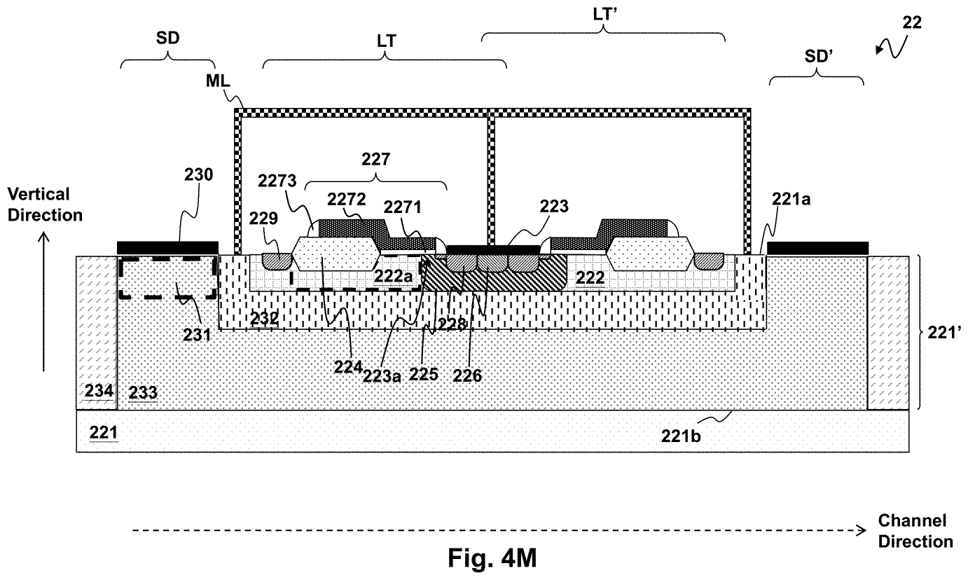

Please refer to FIGS. 4A-4M along with FIG. 2. FIGS. 4A-4M show a manufacturing method of a high voltage device according to an embodiment of the present invention.

First, as shown in FIG. 4A, the semiconductor layer 221′ is formed on the substrate 221. The semiconductor layer 221′, for example, is formed on the substrate 221 by an epitaxial process step, or is a part of the substrate 221. The semiconductor layer 221′ has a top surface 221a and a bottom surface 221b opposite to the top surface 221a in a vertical direction (as indicated by the direction of the solid arrow in FIG. 4A). The semiconductor layer 221′ can be formed by various methods known to a person having ordinary skill in the art, so the details thereof are not redundantly explained here. The substrate 221 is, for example but not limited to, a P-type or N-type semiconductor substrate. Next, as shown in FIG. 4B, the first conductivity type isolation region 233 can be formed by, for example but not limited to, a lithography process step and at least one ion implantation process step, wherein the lithography process step includes forming a photo-resist layer 2211 as a mask, and the ion implantation process step implants first conductivity type impurities into the semiconductor layer 221′ in the form of accelerated ions, to form the first conductivity type isolation region 233 (a part thereof).

Next, as shown in FIG. 4C, the external second conductivity type isolation region 234 and the second conductivity type isolation region 232 can be formed by, for example but not limited to, a lithography process step and at least one ion implantation process step, wherein the lithography process step includes forming a photo-resist layer 2221 as a mask, and the ion implantation process step implants second conductivity type impurities into the semiconductor layer 221′ in the form of accelerated ions, to form the external second conductivity type isolation region 234 (a part thereof) and the second conductivity type isolation region 232 (a part thereof). In one embodiment, the external second conductivity type isolation region 234 and the substrate 221 in combination are defined as a substrate region.

Next, as shown in FIG. 4D, a rest part of the first conductivity type isolation region 233 can be further formed by, for example but not limited to, a lithography process step and at least one ion implantation process step, wherein the lithography process step includes forming a photo-resist layer 2231 as a mask, and the ion implantation process step implants first conductivity type impurities into the semiconductor layer 221′ in the form of accelerated ions, to further form an upper region of the first conductivity type isolation region 233 which lies between the external second conductivity type isolation region 234 and the second conductivity type isolation region 232.

Next, as shown in FIG. 4E, a rest part of the external second conductivity type isolation region 234 can be formed by, for example but not limited to, a lithography process step and at least one ion implantation process step, wherein the lithography process step includes forming a photo-resist layer 2241 as a mask, and the ion implantation process step implants second conductivity type impurities into the semiconductor layer 221′ in the form of accelerated ions, to form an upper region of the external second conductivity type isolation region 234 at a lateral side of the first conductivity type isolation region 233. Besides, as shown in FIG. 4E, a rest part of the second conductivity type isolation region 232 can be formed by, for example but not limited to, a lithography process step and at least one ion implantation process step, wherein the lithography process step includes forming a photo-resist layer 2241 as a mask, and the ion implantation process step implants second conductivity type impurities into the semiconductor layer 221′ in the form of accelerated ions, to form an upper region of the second conductivity type isolation region 232 on a top surface of the first conductivity type isolation region 233.

Next, as shown in FIG. 4F, the well 222 can be formed by, for example but not limited to, a lithography process step and at least one ion implantation process step, wherein the lithography process step includes forming a photo-resist layer 2251 as a mask, and the ion implantation process step implants first conductivity type impurities into the semiconductor layer 221′ in the form of accelerated ions, to form the well 222. At the time point when the well 222 is formed, the drift oxide region 224 has not yet been formed, and the top surface 221a has not yet been completely defined. After the high voltage device 22 has been completely formed, the top surface 221a will be defined as shown by a thick line in FIG. 4G. The well 222 is formed in the semiconductor layer 221′.As shown in FIG. 2G, the well 222 is located beneath the top surface 221a and is in contact with the top surface 221a in the vertical direction.

Next, referring to FIG. 4H, the drift oxide region 224 is formed on and in contact with the top surface 221a. The drift oxide region 224 is for example but not limited to a local oxidation of silicon (LOCOS) structure as shown in the figure, or it may be a shallow trench isolation (STI) structure or a chemical vapor deposition (CVD) structure in other embodiments. The drift oxide region 224 is formed on and in contact with the top surface 221a and is located on and in contact with part of a drift region 222a (as indicated by the thin dashed line frame in the LDMOS device LT shown in FIG. 2 and FIG. 4H).

Next, referring to FIG. 4I, the dielectric layer 2271 and the conductive layer 2272 are formed on the top surface 221a of the semiconductor layer 221′. In the vertical direction (as indicated by the solid arrow in FIG. 4I), as shown in FIG. 2 and FIG. 4I, part of the body region 226 is located vertically below the dielectric layer 2271 and the conductive layer 2272 of the gate 227, and is in contact with the dielectric layer 2271 of the gate 227, to provide the inversion layer 223a of the LDMOS device LT in the ON operation.

Next, referring to FIG. 4J, as shown in the figure, the body region 225 is formed in the well 222, and is located beneath and in contact with the top surface 221a in the vertical direction. The body region 225 has a second conductivity type. The body region 225 can be formed by, for example but not limited to, a lithography process step and an ion implantation process step, wherein the lithography process step includes forming a photo-resist layer 2261 as a mask, and the ion implantation process steps IMP11 and IMP12 implant second conductivity type impurities into the well 222 in the form of accelerated ions with tilt angles respectively, to form the body region 225.

Still referring to FIG. 4J along with FIG. 2, for example, a lightly doped region 2282 is formed after the dielectric layer 2271 and the conductive layer 2272 of the gate 227 are formed, wherein the lightly doped region 2282 is to assist forming a current flowing channel vertically below the spacer layer 2273 in the ON operation. The lightly doped region 2282 for example can be formed by an ion implantation process step IMP2, which implants first conductivity type impurities in the body region 225 in the form of accelerated ions, to form the lightly doped region 2282. Note that the first conductivity type impurity concentration of the lightly doped region 2282 is lower than that of the source 228 or the drain 229, and thus, the effect of the overlap regions of the lightly doped region 2282 with the source 228 and the drain 229 may be ignored.

Next, referring to FIG. 4K, as shown in the figure, the spacer layer 2273 is formed outside the two sides of the conductive layer 2272, to form the gate 227. Next, the source 228 and the drain 229 are formed beneath the top surface 221a and in contact with the top surface 221a. The source 228 and the drain 229 are located at two different sides out of the gate 227 respectively, wherein the source 228 is located in the body region 226, and the drain 229 is located in the well 222 which is away from the body region 226. In the channel direction, the drift region 222a is located in the well 222 between the drain 229 and the body region 226, near the top surface 221a, to serve as the drift current channel for the drift current to flow through in the ON operation of the LDMOS device LT. The source 228 and the drain 229 are located beneath and in contact with the top surface 221a in the vertical direction, and have the first conductivity type. The source 228 and the drain 229 can be formed by, for example but not limited to, a lithography process step and an ion implantation process step IMP3, wherein the lithography process step includes forming a photo-resist layer 2281 as a mask, and the ion implantation process step IMP3 implants first conductivity type impurities into the body region 225 and well 222 in the form of accelerated ions, to form the source 228 and the drain 229 respectively.

Next, referring to FIG. 4L, as shown in the figure, the body contact 226 is formed in the body region 225. The body contact 226 has the second conductivity type, and serves as an electrical contact of the body region 225. The body contact 226 is formed in the body region 225, beneath and in contact with the top surface 221a in the vertical direction. The body contact 226 can be formed by, for example but not limited to, a lithography process step and an ion implantation process step IMP4, wherein the lithography process step includes forming a photo-resist layer 2291 as a mask, and the ion implantation process step IMP4 implants second conductivity type impurities into the body region 225 in the form of accelerated ions, to form the body contact 226.

Next, referring to FIG. 4M, as shown in FIG. 4M, the SBD SD is formed, which includes forming the Schottky metal layer 230 and forming the Schottky semiconductor layer 231. In the manufacturing step for forming the Schottky metal layer 230, the Schottky metal layer 230 is formed on the semiconductor layer 221′. The Schottky metal layer 230 is formed on and in contact with the top surface 221a in the vertical direction. In the manufacturing step for forming the Schottky semiconductor layer 231, the Schottky semiconductor layer 231 is formed in the semiconductor layer 221′. Thus, the Schottky semiconductor layer 231 and the Schottky metal layer 230 form a Schottky contact. In the semiconductor layer 221′, the Schottky semiconductor layer 231 is adjacent to and in contact with the second conductivity type isolation region 232. The Schottky semiconductor layer 231 is located beneath the top surface 221a and is in contact with the top surface 221a in the vertical direction. The second conductivity type isolation region 232 and the body contact 226 are electrically connected to each other via a metal wire ML. In one embodiment, the Schottky semiconductor layer 231 is formed in the first conductivity type isolation region 233. In one embodiment, the first conductivity type isolation region 233 is adjacent to and in contact with the second conductivity type isolation region 232.

Note that, in this embodiment, in the LDMOS devices (including the LDMOS devices LT and LT′), all the wells 222 of are electrically connected to each other, and likely, all the body regions 225, all the body contacts 226, all the gates 227, all the sources 228, and all the drain 229 of the LDMOS devices are respectively electrically connected to each other. In the SBDs (including the SBDs SD and SD′), all the Schottky metal layers 230 are electrically connected to each other, and all the Schottky semiconductor layers 231 are electrically connected to each other. In a preferred embodiment, in the LDMOS device LT, the source 228 and the body contact 226 are electrically connected by a metal silicide layer 223 as shown in the figure.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well, may be added. For another example, the lithography technique is not limited to the mask technology but it can be electron beam lithography, immersion lithography, etc. Therefore, in the same spirit of the present invention, those skilled in the art can think of various equivalent variations and modifications, which should fall in the scope of the claims and the equivalents.

What is claimed is:

1. A high voltage device for use as an up-side switch in a power stage circuit of a switching regulator, the high voltage device comprising:
at least one lateral diffused metal oxide semiconductor (LDMOS) device, wherein the at least one LDMOS device includes:
a well, which has a first conductivity type, and is formed in a semiconductor layer;
a body region, which has a second conductivity type, and is formed in the well;
a gate, which is formed on the well and is connected to the well; and
a source and a drain, which have the first conductivity type, and are located at different sides out of the gate respectively, wherein the source is located in the body region, and the drain is located in the well;
a second conductivity type isolation region, which is formed in the semiconductor layer, wherein the second conductivity type isolation region encompasses a lateral side of and a bottom side of the at least one LDMOS device, and wherein the second conductivity type isolation region is electrically connected to the body region; and
at least one Schottky barrier diode (SBD), wherein the at least one SBD includes:
a Schottky metal layer, which is formed on the semiconductor layer, and is electrically connected to an offset voltage; and
a Schottky semiconductor layer, which has the first conductivity type, and is formed in the semiconductor layer, wherein the Schottky semiconductor layer and the Schottky metal layer form a Schottky contact, and wherein in the semiconductor layer, the Schottky semiconductor layer is adjacent to and in contact with the second conductivity type isolation region;
wherein part of the body region, which is between a boundary thereof and the source, and is vertically below the gate, forms an inversion region which serves as an inversion current channel in an ON operation of the LDMOS device;
wherein part of the well between the body region and the drain is a drift region, which serves as a drift current channel in the ON operation of the LDMOS device.

2. The high voltage device of claim 1, wherein the at least one SBD is located in a first conductivity type isolation region of the high voltage device, and wherein the first conductivity type isolation region is located outside of the second conductivity type isolation region, and the first conductivity type isolation region encompasses a lateral side of and a bottom side of the second conductivity type isolation region.

3. The high voltage device of claim 2, further comprising:
a substrate region, which has the second conductivity type and which encompasses a lateral side of and a bottom side of the first conductivity type isolation region.

4. The high voltage device of claim 1, wherein the at least one LDMOS device further includes:
a drift oxide region, which is formed on the drift region, wherein the drift oxide region includes: a LOCal Oxidation of Silicon (LOCOS) structure, a Shallow Trench Isolation (STI) structure or a Chemical Vapor Deposition (CVD) structure.

5. The high voltage device of claim 1, wherein the gate includes:
a dielectric layer, which is formed on the body region and the well and is connected to the body region and the well;
a conductive layer, which serves as an electrical contact of the gate, wherein the conductive layer is formed on the dielectric layer and is connected to the dielectric layer; and
a spacer layer, which is formed out of two sides of the conductive layer and serves as an electrically insulative layer at two sides of the gate.

6. The high voltage device of claim 1, wherein the Schottky metal layer is electrically connected to a current outflow end of the power stage circuit.

7. A manufacturing method of a high voltage device, wherein the high voltage device is for use as an up-side switch in a power stage circuit of a switching regulator; the manufacturing method comprising:
forming at least one lateral diffused metal oxide semiconductor (LDMOS) device, by manufacturing steps including:
forming a well in a semiconductor layer, wherein the well has a first conductivity type;
forming a body region in the well, wherein the body region has a second conductivity type;
forming a gate on the well and in contact with the well; and
forming a source and a drain having the first conductivity, wherein the source and the drain are located at different sides out of the gate respectively, wherein the source is located in the body region, and the drain is located in the well;
forming a second conductivity type isolation region in the semiconductor layer, wherein the second conductivity type isolation region encompasses a lateral side of and a bottom side of the at least one LDMOS device, and wherein the second conductivity type isolation region is electrically connected to the body region; and
forming at least one Schottky barrier diode (SBD), by manufacturing steps including:
forming a Schottky metal layer on the semiconductor layer, wherein the Schottky metal layer is electrically connected to an offset voltage; and
forming a Schottky semiconductor layer in the semiconductor layer, wherein the Schottky semiconductor layer and the Schottky metal layer form a Schottky contact, and wherein in the semiconductor layer, the Schottky semiconductor layer is adjacent to and in contact with the second conductivity type isolation region, wherein the Schottky semiconductor layer has the first conductivity type;
wherein part of the body region, which is between a boundary thereof and the source, and is vertically below the gate, forms an inversion region which serves as an inversion current channel in an ON operation of the LDMOS device;
wherein part of the well between the body region and the drain is a drift region, which serves as a drift current channel in the ON operation of the LDMOS device.

8. The manufacturing method of claim 7, further comprising:
forming a first conductivity type isolation region in the semiconductor layer of the high voltage device, so that the at least one SBD is located in the first conductivity type isolation region, wherein the first conductivity type isolation region is located outside of the second conductivity type isolation region, and the first conductivity type isolation region encompasses a lateral side of and a bottom side of the second conductivity type isolation region.

9. The manufacturing method of claim 8, further comprising:
forming a substrate region at a lateral side of and a bottom side of the first conductivity type isolation region, wherein the substrate region encompasses the lateral side of and the bottom side of the first conductivity type isolation region, wherein the substrate region has the second conductivity type.

10. The manufacturing method of claim 7, further comprising:
forming a drift oxide region on the drift region, wherein the drift oxide region includes: a LOCal Oxidation of Silicon (LOCOS) structure, a Shallow Trench Isolation (STI) structure or a Chemical Vapor Deposition (CVD)structure.

11. The manufacturing method of claim 7, wherein the step for forming the gate includes:
forming a dielectric layer on the body region and the well, wherein the dielectric layer is connected to the body region and the well;
forming a conductive layer on the dielectric layer, wherein the conductive layer is connected to the dielectric layer and the conductive layer serves as an electrical contact of the gate; and
forming a spacer layer out of two sides of the conductive layer, wherein the spacer layer serves as an electrically insulative layer at two sides of the gate.

12. The manufacturing method of claim 7, wherein the Schottky metal layer is electrically connected to a current outflow end of the power stage circuit.
